(19) United States
(12) Patent Application Publication
(10) Pub. No.: US 2009/0140890 A1
(43) Pub. Date: Jun. 4, 2009

(54) KEYBOARD

(75) Inventors: SHAN-QIN BAO, Shenzhen City (CN); ZHANG-BO HUANG, Shenzhen City (CN); HAI-YAN WANG, Shenzhen City (CN); AI-LIAN LIU, Shenzhen City (CN); GEN-HUA LIU, Shenzhen City (CN); WEN-QING DU, Shenzhen City (CN)

Correspondence Address: PCE INDUSTRY, INC.;ATT. Steven Reiss, 458 E. LAMBERT ROAD, FULLERTON, CA, 92835, US

(73) Assignees: HONG FU JIN PRECISION INDUSTRY (ShenZhen) CO., LTD, Shenzhen City (CN); HON HAI PRECISION INDUSTRY CO., LTD., Tu-Cheng (TW)

(21) Appl. No.: 12/178,647

(22) Filed: Jul. 24, 2008

(30) Foreign Application Priority Data
Nov. 30, 2007 (CN) 200710202800.1

(51) Int. Cl. H03M 11/00

(52) U.S. Cl. 341/26

(57) ABSTRACT

An exemplary keyboard includes a row-and-column scanning matrix and a lock switch. The row-and-column scanning matrix includes a controller including a plurality of input ports and output ports, a plurality of keys electrically connecting the plurality of input ports to the plurality of output ports of the controller via a plurality of row conductive lines and column conductive lines when actuated. The lock switch connected in series with one or more of the plurality of keys is configured for disabling the one or more of the plurality of keys when opened.

### BACKGROUND

1. Field of the Invention

The present invention relates to a keyboard.

2. Description of Related Art

Keyboards are widely used for inputting information into data processing systems, such as computer systems. Physically, a keyboard is an arrangement of input keys having characters engraved or printed on the keys. There are several types of keyboards available. The types are defined by the number of keys on a keyboard. The number of keys varies from the standard of 101 keys introduced in the late 1980s to the 104 keys on a 104-key keyboards and all the way up to 130 keys or more. Some keys on the keyboard are function keys. The function keys are programmed or programmable keys that can simulate one or multiple functions such as starting a web browser, providing volume control, or starting an E-mail client. For example, by pressing a key known as the Windows® key the Start menu, in Windows®' standard Explorer shell, is activated.

Certain functions requires pressing and holding several keys simultaneously or sequentially. For example, Ctrl+Alt could be a keystroke combination that is frequently used in computer games. However, when using these keystroke combinations, some other multi-function keys may be triggered by mistake. For example, the Windows® key is located between the Ctrl and the Alt keys and can inadvertently be pressed when trying to press the Ctrl and Alt keys simultaneously, a common practice in game playing.

Therefore, an improved keyboard is needed to address the aforementioned deficiency and inadequacies.

### SUMMARY

An exemplary keyboard includes a row-and-column scanning matrix and a lock switch. The row-and-column scanning matrix includes a controller including input ports and output ports, keys electrically connecting the input ports to the output ports of the controller via row conductive lines and column conductive lines when actuated. The lock switch connected in series with one or more of the keys is configured for disabling the one or more of the keys when opened.

Other advantages and novel features of the present invention will become more apparent from the following detailed description of an embodiment/embodiments when taken in conjunction with the accompanying drawings, in which:

### BRIEF DESCRIPTION OF THE DRAWINGS

FIG. 1 is a schematic diagram of a keyboard in accordance with a first exemplary embodiment.

FIG. 2 is a schematic circuit diagram of the keyboard of FIG. 1.

FIG. 3 is a schematic circuit diagram of a keyboard in accordance with a second exemplary embodiment.

FIG. 4 is a schematic circuit diagram of a keyboard in accordance with a third exemplary embodiment.

### DETAILED DESCRIPTION

References will now be made to the drawings to describe preferred embodiments of the present keyboard.

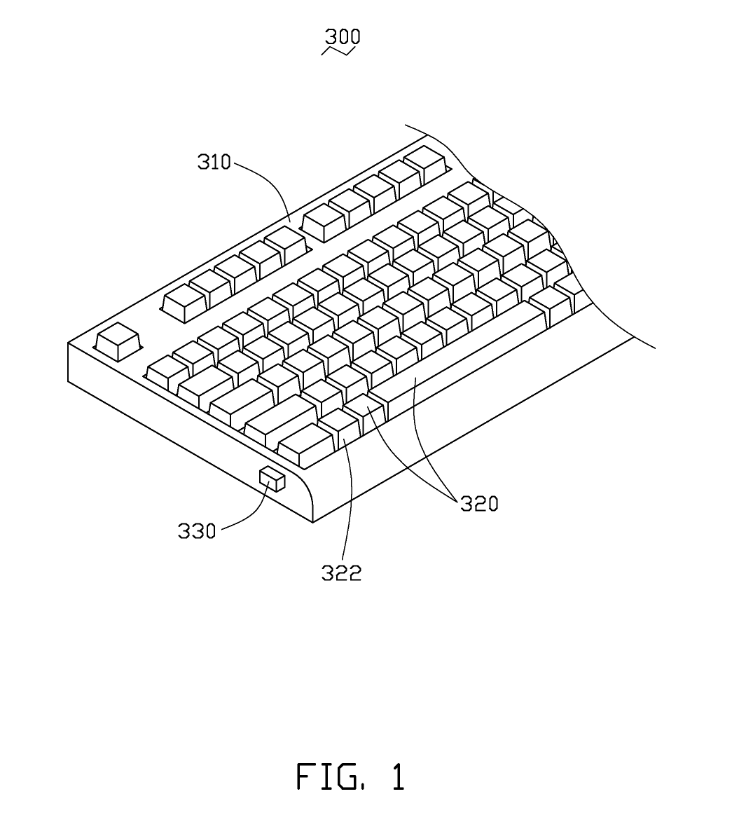

Referring to FIG. 1, a keyboard 300 in accordance with an exemplary embodiment includes a housing 310, a plurality of keys 320 and a lock switch 330 disposed on the housing 310. The plurality of keys 320 are configured for inputting data or commands. The lock switch 330 is used for disabling one or more of the keys 320 when opened. In the exemplary embodiment, a first key 322 is used as an example of being disabled and enabled by the lock switch 330.

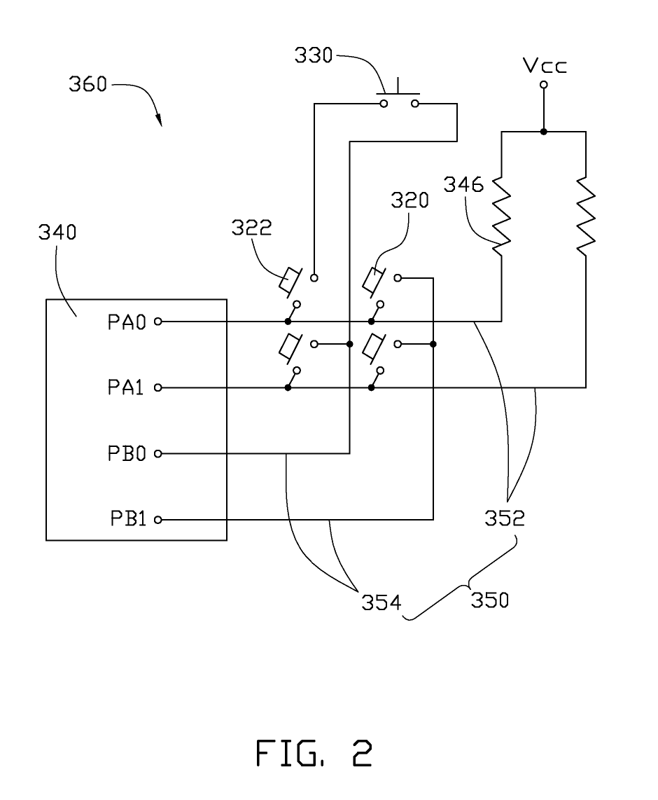

Referring also to FIG. 2, the keyboard 300 further includes a controller 340 for receiving the data or commands from the plurality of keys 320, and a conducting matrix 350 for connecting the plurality of keys 320 to the controller 340. The controller 340 includes a plurality of input ports (PA0, PA1, etc.) and a plurality of output ports (PB0, PB1, etc.). The conducting matrix 350 includes a plurality of row conductive lines (row lines for short) 352 and column conductive lines (column lines for short) 354. Each of the plurality of input ports (PA0, PA1, etc.) is connected to an end of one of the plurality of row lines 352. Each of the plurality of output ports (PB0, PB1, etc.) is connected to an end of one of the plurality of column lines 354. The other end of each of the plurality of row lines 352 is connected to a power supply Vcc via a conductive element 346, such as a resistor. The power supply Vcc is used for supplying a voltage (also labeled as Vcc) to the row lines.

The keys 320 are disposed at intersections of the conducting matrix 350 to electrically connect the plurality of row lines 352 to the plurality of column lines 354 when actuated. In other words, one of the plurality of input ports (PA0, PA1, etc.) is connected to the corresponding one of the plurality of output ports (PB0, PB1, etc.) when one of the plurality of keys 320 is actuated. For example, one of the plurality of keys 320 is coupled between the input port PA0 and the output port PB1 via one of the plurality of row lines 352 and one of the plurality of column lines 354. When the one of the plurality of keys 320 is actuated, the input port PA0 is connected to the output port PB1. The controller 340, the conducting matrix 350, the keys 320, the power supply Vcc, and the conductive elements 346 form a row-and-column scanning matrix 360.

In the exemplary embodiment, the lock switch 330 is disposed at a left side surface of the housing 310 for disabling the first key 322 when opened. The lock switch 330 is a normally closed switch. That is, the lock switch 330 has two states, an opened state and a closed state. In the closed state, the lock switch 330 will establish an electrical connection, in the opened state, the lock switch 330 will cutoff the electrical connection. In the exemplary embodiment the lock switch 330, by default, is normally in the closed state. The lock switch 330 may be a push-button switch, a toggle switch, a dolly switch, a rocker switch, or any type of mechanical switches. The lock switch 330 and the first key 322 are connected in series. In detail, a contact of the first key 322 is connected to the input port PA0, the other contact of the first key 322 is connected to a contact of the lock switch 330, and the other contact of the lock switch 330 is connected to the output port PB0.

In operation, when the lock switch 330 is in the closed state, the first key 322 can be used normally, just like any other key of the plurality of keys 320. The output ports (PB0, PB1, etc.) of the controller 340 all provide low voltages (may be 0 volts). When no key is actuated, the input ports (PA0, PA1, etc.) receive a high voltage that equals to Vcc.

When one of the plurality of keys 320 is actuated, voltages on the corresponding one of the plurality of row lines 352 and on one of the plurality of input ports (PA0, PA1, etc.) are pulled down from the high voltage to the low voltage to signal the controller 340 that one of the plurality of keys 320 is actuated. In response, the controller 340 sequentially outputs the low voltage to each of the plurality of column lines 354 in sequence, and scans all the row lines 352. When one of the input ports (PA0, PA1, etc.) detects a low voltage on a particular one of the plurality of row lines 352, and the low voltage is supplied to a particular one of the plurality of column lines 354 at the moment, the controller 340 determines that the actuated key is disposed at the intersection of the particular one of the plurality of column lines 354 and the particular one of the plurality of row lines 352.

When the lock switch 330 is opened, the first key 322 is disconnected from corresponding one of the plurality of row lines 352 or column lines 354. Even if the first key 322 is actuated, the corresponding ones of the plurality of row lines 352 and column lines 354 are still disconnected. Therefore, the controller 340 cannot detect the first key 322, that is, the first key 322 is disabled/locked.

In the exemplary embodiment, the first key 322 is the Windows® key. When a game or certain application is invoked in a device connected to the keyboard 300, the Windows® key can be locked via the lock switch 330. As a result, when the Windows® key is accidentally pressed, when performing input operations involving the input keys around the Windows® key such as Alt, Ctrl, Shift, etc, the function performed by pressing the Windows® key is disabled.

Alternative embodiments will become apparent to those skilled in the art to which the present invention pertains without departing from its spirit and scope.

For example, the lock switch 330 may be disposed at another location of the housing 310. The lock switch 330 may also be used for disabling/locking more than one keys.

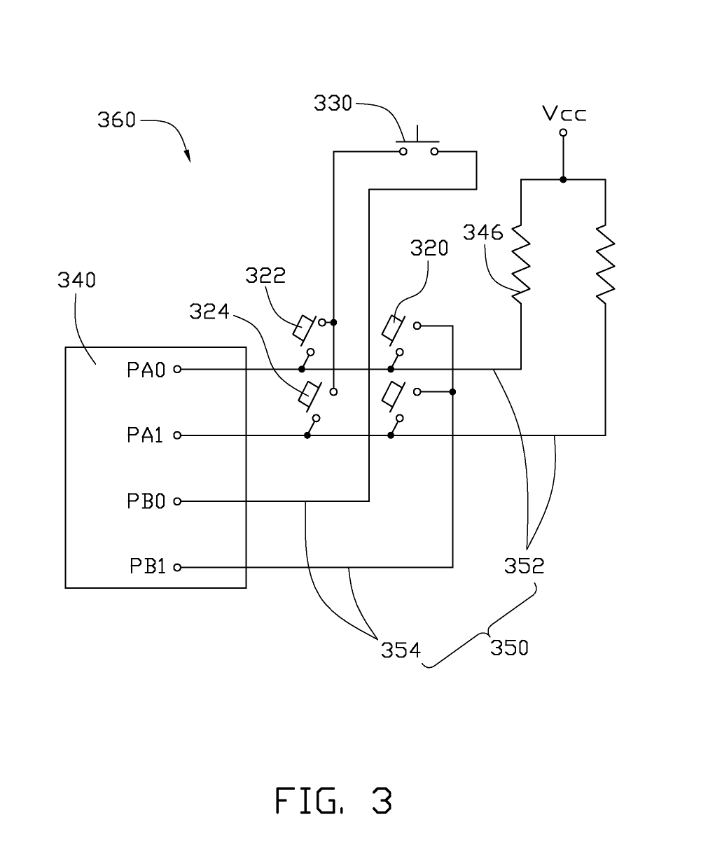

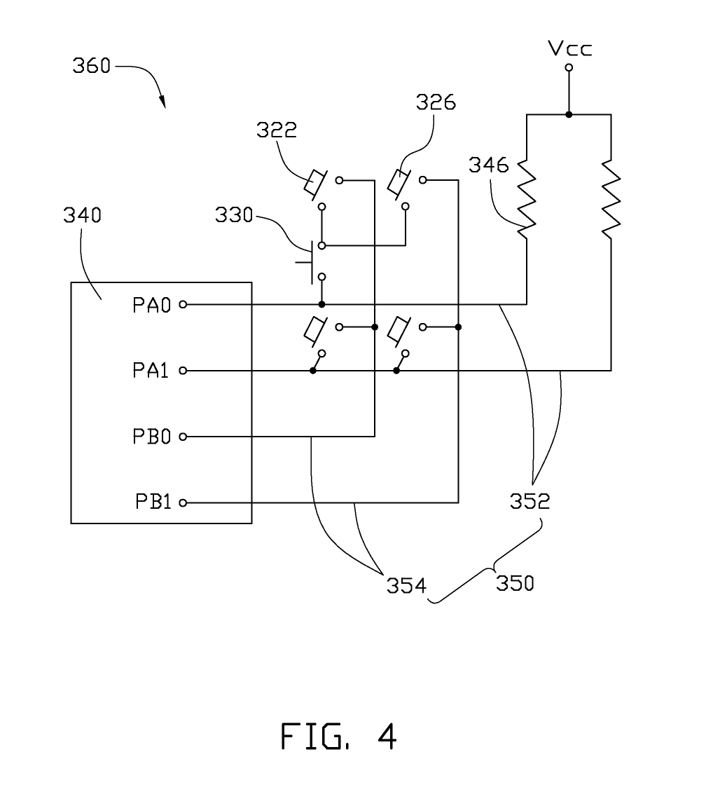

Referring to FIGS. 3 and 4, the lock switch 330 of the keyboard 300 in accordance with a second and a third exemplary embodiments is connected in series with the more than one keys of the plurality of keys 320, respectively.

The more than one keys connected in series with the lock switch 330 should belong to the same column or the same row of the conducting matrix 350. In other words, the more than one keys connected in series with the lock switch 330 are disposed in the conducting matrix 350 to connect one of the plurality of column lines 354 to more than one of the plurality of row lines 352 via the lock switch 330. When the lock switch 330 is opened, all the more than one keys connected in series with the lock switch 330 are locked simultaneously.

In detail, in the second exemplary embodiment (FIG. 3), the first key 322 and a second key 324 are connected in series with the lock switch 330. A contact of the first key 322 is connected to the input port PA0. A contact of the second key 324 is connected to the input port PA1. The other contacts of the first and second keys 322, 324 are connected to a contact of the lock switch 330. The other contact of the lock switch 330 is connected to the output port PB0. When the lock switch 330 is opened, the first and second keys 322, 324 are locked simultaneously.

In the third exemplary embodiment (FIG. 4), the first key 322 and a third key 326 are connected in series with the lock switch 330. A contact of the first key 322 is connected to the output port PB0. A contact of the third key 326 is connected to the output port PB1. The other contacts of the first and third keys 322, 326 are connected to a common junction, which in turn is connected to a contact of the lock switch 330. The other contact of the lock switch 330 is connected to the input port PA0. When the lock switch 330 is opened, the first and third keys 322, 326 are locked simultaneously.

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A keyboard comprising:
a row-and-column scanning matrix comprising:
a controller comprising a plurality of input ports and output ports; and
a plurality of keys electrically connecting the plurality of input ports to the plurality of output ports of the controller via a plurality of row conductive lines and column conductive lines when the plurality of keys are actuated; and
a lock switch connected in series with one or more of the plurality of keys for disabling the one or more of the plurality of keys when opened.

2. The keyboard as claimed in claim 1, further comprising a housing for receiving the row-and-column scanning matrix and the lock switch.

3. The keyboard as claimed in claim 1, wherein the lock switch is connected in series with more than one of the plurality of keys for disabling the more than one of the plurality of keys when opened, a contact of each of the more than one of the plurality of keys is connected to one of the plurality of input ports of the controller, another contact of each of the more than one of the plurality of keys is connected to a contact of the lock switch, and another contact of the lock switch is connected to one of the plurality of output ports of the controller.

4. The keyboard as claimed in claim 1, wherein the lock switch is connected in series with more than one of the plurality of keys for disabling the more than one of the plurality of keys when opened, a contact of each of the more than one of the plurality of keys is connected to one of the plurality of output ports of the controller, another contact of each of the more than one of the plurality of keys is connected to a contact of the lock switch, and another contact of the lock switch is connected to one of the plurality of input ports of the controller.

5. The keyboard as claimed in claim 1, wherein the one of the plurality of keys connected in series with the lock switch is the Windows® key of the keyboard.

6. The keyboard as claimed in claim 1, wherein the lock switch is a push-button switch or a toggle switch.

7. The keyboard as claimed in claim 2, wherein the lock switch is disposed at one side of the housing.

8. The keyboard as claimed in claim 2, wherein the lock switch is a normally closed switch.

9. A keyboard comprising:
a controller comprising input ports and output ports;
first conductive lines connected to corresponding input ports of the controller;
second conductive lines connected to corresponding output ports of the controller, and the first and second conductive lines forming a conducting matrix;
keys disposed at intersections of the conducting matrix to electrically connect corresponding first conductive lines to second conductive lines when actuated; and
a lock switch connected in series with one or more of the keys for disabling the one or more of the keys when opened.

10. The keyboard as claimed in claim 9, further comprising a housing for receiving the controller, the conducting matrix, the keys, and the lock switch.

11. The keyboard as claimed in claim 9, wherein the lock switch is connected in series with more than one of the keys for disabling the more than one of the keys when opened, the more than one of the keys are disposed in the conducting matrix to connect one of the first conductive lines to more than one of the second conductive lines via the lock switch.

12. The keyboard as claimed in claim 9, wherein the lock switch is connected in series with more than one of the keys for disabling the more than one of the keys when opened, the more than one of the keys are disposed in the conducting matrix to connect one of the second conductive lines to more than one of the first conductive lines via the lock switch.

13. The keyboard as claimed in claim 9, wherein the lock switch is connected in series with one of the keys for disabling the one of the keys when opened, the one of the keys is the Windows® key of the keyboard.

14. The keyboard as claimed in claim 9, wherein the lock switch is a push-button switch or a toggle switch.

15. The keyboard as claimed in claim 10, wherein the lock switch is disposed at a side of the housing.

16. The keyboard as claimed in claim 10, wherein the lock switch is a normally closed switch.
